(19) United States
(12) Patent Application Publication
(10) Pub. No.: US 2011/0146761 A1
(43) Pub. Date: Jun. 23, 2011

(54) SOLAR MODULE ARRAY AND GROUNDING STRUCTURE THEREOF

(75) Inventors: Chen-Yu Yang, Keelung City (TW); Yu-Ting Lin, Hsinchu City (TW); Cheng-Hsin Chen, Yuanlin Township (TW)

(73) Assignee: Du Pont Apollo Limited, Pak Shek Kok (HK)

(21) Appl. No.: 12/965,809

(22) Filed: Dec. 10, 2010

Related U.S. Application Data
(60) Provisional application No. 61/289,013, filed on Dec. 22, 2009.

(51) Int. Cl. H01L 31/048

(52) U.S. Cl. 136/251

(57) ABSTRACT

A solar module array includes a plurality of solar cell modules. Each solar cell module includes a solar cell panel and a metal frame for securing the solar cell panel. The metal frame includes an upper horizontal member, a lower horizontal member and a vertical member. The upper horizontal member is for holding the solar cell panel. The vertical member is interconnected between the upper and lower horizontal members, and a set of bolt and nut electrically connect any adjacent-two vertical members. In an alternate way, the auxiliary member extends from the vertical member, and a set of bolt and nut electrically connect two overlapped auxiliary members of any adjacent-two vertical members.

### RELATED APPLICATIONS

This application claims priority to U.S. Provisional Application Ser. No. 61/289,013, filed Dec. 22, 2009, which is herein incorporated by reference.

### BACKGROUND

1. Field of Invention

The present invention relates to a solar cell array.

2. Description of Related Art

In recent years, awareness of ecological problems has been raised worldwide. Among other things, the global warming resulting from CO₂ emission is a serious concern, and clean energy has been increasingly desired. In such a circumstance, a solar cell shows great promise to serve as a source of clean energy in terms of its safety and operability.

The solar cell includes a photoelectric conversion layer for converting light into electricity, typical materials of which include single-crystal silicon semiconductor, polycrystalline silicon semiconductor, amorphous silicon-based semiconductor, groups III-V compound semiconductor, groups II-VI compound semiconductor and groups I-III-VI2 compound semiconductor.

When using solar cell modules, durability with respect to the external environment, including temperature, humidity, and impact, is required. Therefore, ordinary solar cell modules are constructed such that: solar cells are sealed with a filler; a weather-resistant film or glass is provided as a protective material on the top surface side thereof; and a reinforcing member or outer member is mounted on the periphery and bottom surface thereof. Most of such members are made of a metal.

From the viewpoint of electrical safety and protecting the solar cell, measures are taken to electrically ground the outer conductor members of solar cell modules. In this way, even if one touches the outer conductor member of a solar cell module, the person does not receive an electrical shock. Moreover, the solar cell itself would not be damaged due to a leakage current from the outer conductor members of solar cell modules.

### SUMMARY

In accordance with an aspect of the present invention, a solar module array includes a plurality of solar cell modules. Each solar cell module includes a solar cell panel and a metal frame for securing the solar cell panel. The metal frame includes an upper horizontal member, a lower horizontal member and a vertical member. The upper horizontal member is for holding the solar cell panel. The vertical member is interconnected between the upper and lower horizontal members. A set of bolt and nut electrically connect any adjacent-two vertical members.

In accordance with another aspect of the present invention, a solar module array includes a plurality of solar cell modules. Each solar cell module includes a solar cell panel and a metal frame for securing the solar cell panel. The metal frame includes an upper horizontal member, a lower horizontal member, a vertical member and an auxiliary member. The upper horizontal member is for holding the solar cell panel. The vertical member is interconnected between the upper and lower horizontal members. The auxiliary member extends from the vertical member. A set of bolt and nut electrically connect two overlapped auxiliary members of any adjacent-two vertical members.

According to one embodiment of the present invention, at least one of the metal frames is electrically connected with a grounding portion.

According to another embodiment of the present invention, the metal frame is made from aluminum.

According to another embodiment of the present invention, the solar module array further includes a metal support bracket and the lower horizontal member is secured over the metal support bracket.

According to another embodiment of the present invention, the bolt has a gold-coated or silver-coated threaded portion.

According to another embodiment of the present invention, the bolt comprises steel.

According to another embodiment of the present invention, any adjacent-two vertical members have respective threaded holes to be inserted by the bolt.

According to another embodiment of the present invention, the gold-coated or silver-coated threaded portion is in contact with an inner surface of the respective threaded hole.

According to another embodiment of the present invention, the lower horizontal member is generally in parallel with the upper horizontal member.

According to another embodiment of the present invention, the auxiliary member is generally perpendicular to the vertical member.

According to another embodiment of the present invention, the two overlapped auxiliary members have respective threaded holes to be inserted by the bolt. It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a solar module array according to one embodiment of this invention;

FIG. 2 illustrates a cross-sectional view of the solar module array as illustrated in FIG. 1;

FIG. 3 illustrates an enlarged-view of a connection part between two adjacent solar cell modules as illustrated in FIG. 2;

FIG. 4 illustrates a cross-sectional view of the solar module array according to another embodiment of this invention; and

FIG. 5 illustrates an enlarged-view of a connection part between two adjacent solar cell modules as illustrated in FIG. 4.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

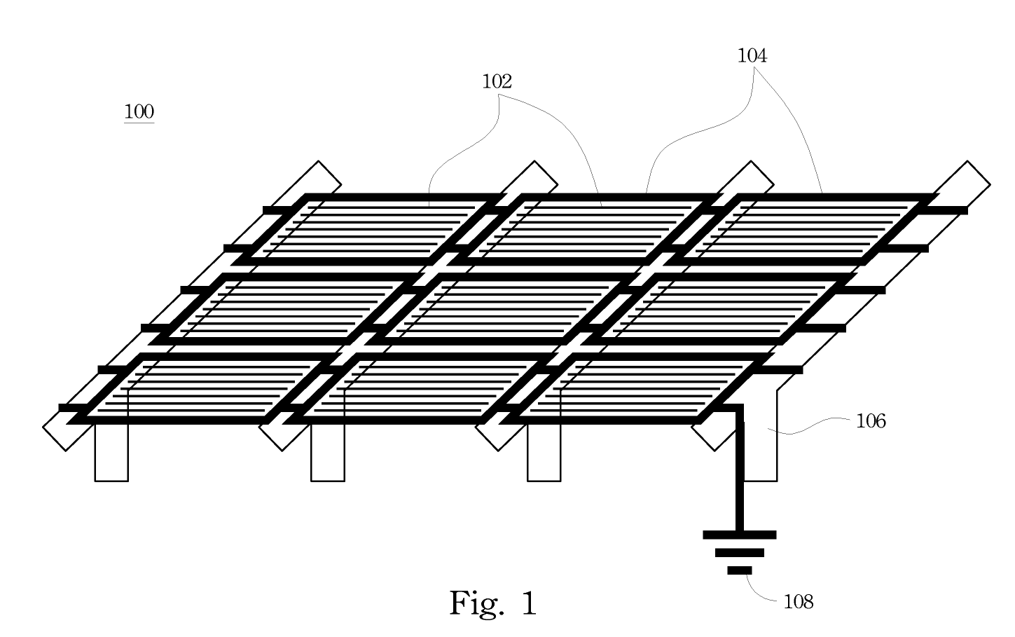

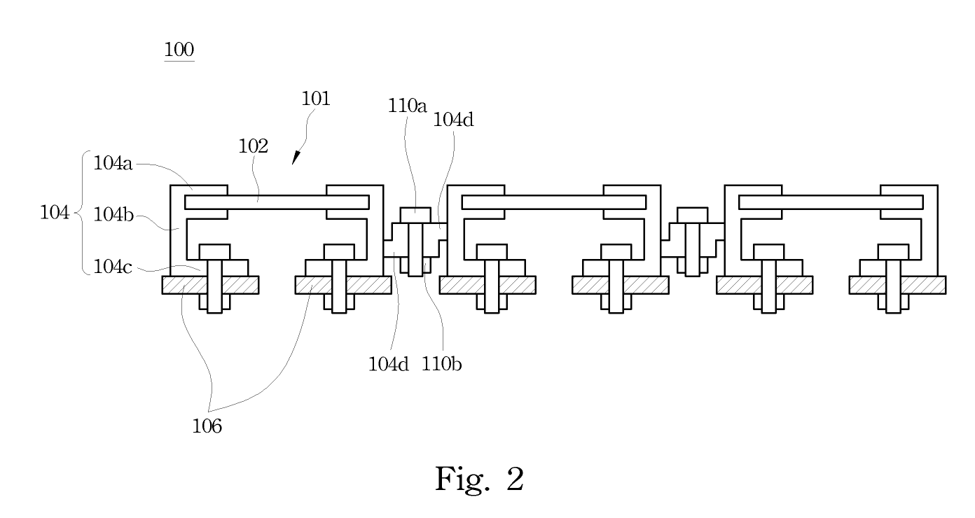

FIG. 1 illustrates a solar module array according to one embodiment of this invention. FIG. 2 illustrates a cross-sectional view of the solar module array as illustrated in FIG. 1. A solar module array 100 includes a plurality of solar cell modules 101 arranged side by side to form an array. Each solar cell module 101 consists of a solar cell panel 102 and an aluminum frame 104. The aluminum frame 104 is to secure the solar cell panel 102. The aluminum frame 104 is a unitary frame, but divided into three parts: an upper horizontal member 104a, a vertical member 104b and a lower horizontal member 104c for easily explaining this embodiment. The lower horizontal member 104c is generally in parallel with the upper horizontal member 104a. The vertical member 104b is interconnected between the upper and lower horizontal members (104a, 104b). The upper horizontal member 104a is to hold the solar cell panel 102. The lower horizontal member 104c is secured over a metal support bracket 106 with several sets of bolts and nuts.

In order to establish a grounding system for the solar module array 100, all aluminum frames 104 need to be electrically interconnected and at least one of the aluminum frames 104 needs to be electrically connected with an outer grounding portion 108. In this embodiment, steel bolts 110a and nuts 110b serve as the electrical connection interfaces among aluminum frames 104. In particular, an auxiliary member 104d extends from the vertical member 104b to a gap between any adjacent-two aluminum frames 104. In this embodiment, the auxiliary member 104d is generally perpendicular to the vertical member 104b. One or more sets of bolts 110a and nuts 110b are used to interconnect two overlapped auxiliary members 104d. With this regard, all aluminum frames 104 can be electrically connected with the outer grounding portion 108.

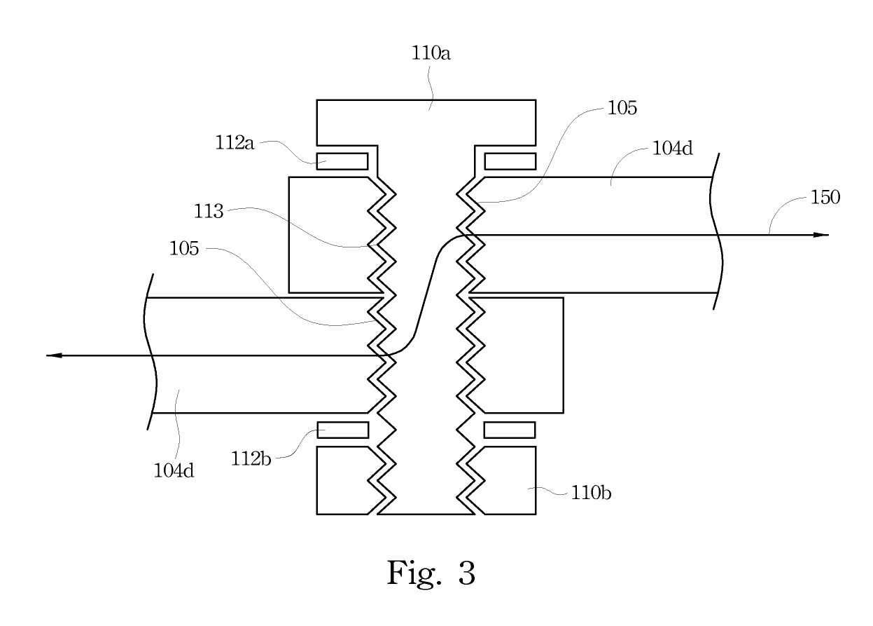

FIG. 3 illustrates an enlarged-view of a connection part between two adjacent solar cell modules as illustrated in FIG. 2. In this FIG. 3, two overlapped auxiliary members 104d are electrically interconnected by a set of bolt 110a and nut 110b. The bolt 110a has a threaded portion 113. The threaded portion 113 may be gold-coated or sliver-coated to enhance its contact performance, i.e. reducing contact resistance. A pair of washers 112a and 112b are used herein to avoid the bolt 110a and nut 110b from scratching an outer surface of the auxiliary member 104d. The outer surface of the auxiliary member 104d and other parts of the aluminum frame 104 may be anodized to form a protection layer (not illustrated in the drawings) so as to be anti-oxided. It should be noted that a major electrical connection path 150 is established through the threaded interface between the auxiliary member 104d and the bolt 110a. In the FIG. 3, for clearly illustrating every component, a gap is left between the threaded hole 105 and the threaded portion 113 of the bolt 110a. In actual practice, the threaded portion 113 of the bolt 110a is in contact with an inner surface of the threaded hole 105 such that the major electrical connection path 150 can be established.

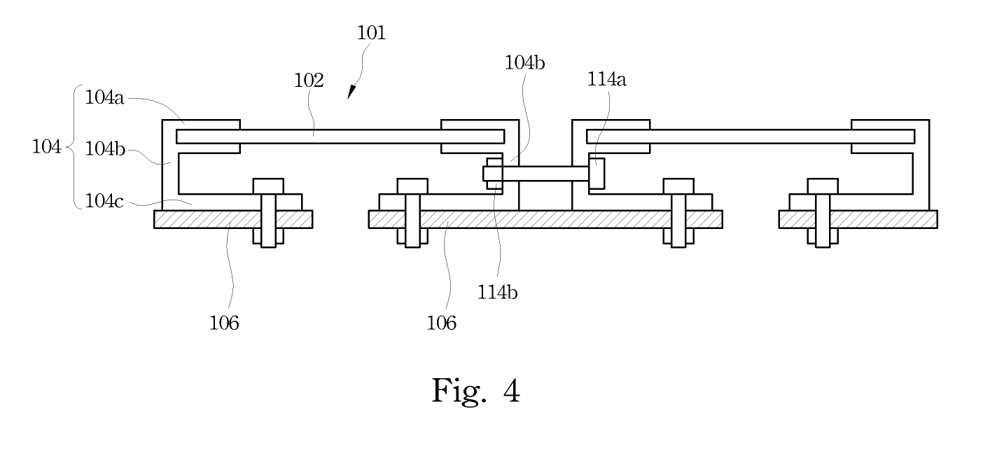

FIG. 4 illustrates a cross-sectional view of the solar module array according to another embodiment of this invention. This embodiment is slightly different from the embodiment of FIG. 2 in that a set of steel bolt 114a and nut 114b are used to electrically interconnect two adjacent vertical members 104b. The auxiliary member 104d is not necessary and thus removed.

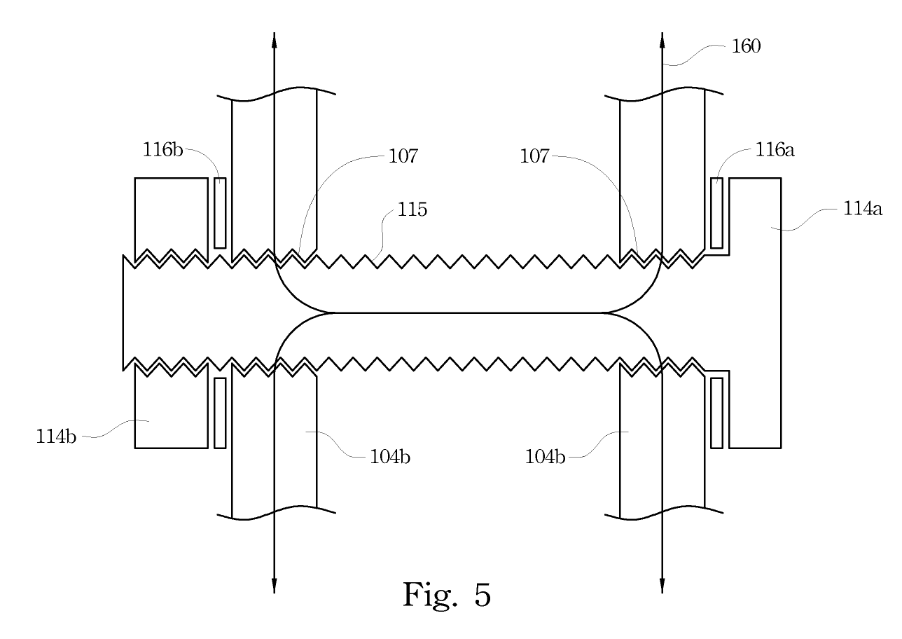

FIG. 5 illustrates an enlarged-view of a connection part between two adjacent solar cell modules as illustrated in FIG. 4. In detailed view, the bolt 114a has a threaded portion 115. The threaded portion 115 may be gold-coated or sliver-coated to enhance its contact performance, i.e. reducing contact resistance. Two adjacent vertical members 104b have respective threaded holes 107 to be inserted by the bolt 114a. A pair of washers 116a and 116b may be used herein to avoid the bolt 114a and nut 114b from scratching an outer surface of the vertical member 104b. The outer surface of the vertical member 104b and other parts of the aluminum frame 104 may be anodized to form a protection layer (not illustrated in the drawings) so as to be anti-oxided. In this drawing, for clearly illustrating every component, a gap is left between the threaded hole 107 and the threaded portion 115 of the bolt 114a. In actual practice, the threaded portion 115 of the bolt 114a is in contact with an inner surface of respective threaded holes 107 such that a major electrical connection path 160 can be established.

According to the discussed embodiments, the solar module array with improved grounding structure is equipped with sets of bolts and nuts to electrically interconnect adjacent aluminum frames instead of using cables to electrically interconnect adjacent aluminum frames. Therefore, the improved grounding structure of the solar module array would be more durable with respect to the external environment, including temperature, humidity, and impact.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A solar module array comprising:
a plurality of solar cell modules, each solar cell module comprising:
a solar cell panel;
a metal frame for securing the solar cell panel, the metal frame comprising:
an upper horizontal member for holding the solar cell panel;
a lower horizontal member; and
a vertical member interconnected between the upper and lower horizontal members; and
a set of bolt and nut electrically connecting any adjacent-two vertical members.

2. The solar module array of claim 1, wherein at least one of the metal frames is electrically connected with a grounding portion.

3. The solar module array of claim 1, wherein the metal frame is made from aluminum.

4. The solar module array of claim 1, further comprising a metal support bracket and the lower horizontal member being secured over the metal support bracket.

5. The solar module array of claim 1, wherein the bolt has a gold-coated or silver-coated threaded portion.

6. The solar module array of claim 5, wherein the bolt comprises steel.

7. The solar module array of claim 5, wherein any adjacent-two vertical members have respective threaded holes to be inserted by the bolt.

8. The solar module array of claim 7, wherein the gold-coated or silver-coated threaded portion is in contact with an inner surface of the respective threaded hole.

9. The solar module array of claim 1, wherein the lower horizontal member is generally in parallel with the upper horizontal member.

10. A solar module array comprising:
a plurality of solar cell modules, each solar cell module comprising:
a solar cell panel;
a metal frame for securing the solar cell panel, the metal frame comprising:
an upper horizontal member for holding the solar cell panel;
a lower horizontal member;
a vertical member interconnected between the upper and lower horizontal members; and
an auxiliary member extending from the vertical member; and
a set of bolt and nut electrically connecting two overlapped auxiliary members of any adjacent-two vertical members.

11. The solar module array of claim 10, wherein the auxiliary member is generally perpendicular to the vertical member.

12. The solar module array of claim 10, wherein at least one of the metal frames is electrically connected with a grounding portion.

13. The solar module array of claim 10, wherein the metal frame is made from aluminum.

14. The solar module array of claim 10, further comprising a metal support bracket and the lower horizontal member being secured over the metal support bracket.

15. The solar module array of claim 10, wherein the bolt has a gold-coated or silver-coated threaded portion.

16. The solar module array of claim 15, wherein the bolt comprises steel.

17. The solar module array of claim 15, wherein the two overlapped auxiliary members have respective threaded holes to be inserted by the bolt.

18. The solar module array of claim 17, wherein the gold-coated or silver-coated threaded portion is in contact with an inner surface of the respective threaded hole.

19. The solar module array of claim 10, wherein the lower horizontal member is generally in parallel with the upper horizontal member.
